(19) United States
(12) Patent Application Publication
(10) Pub. No.: US 2020/0408910 A1
(43) Pub. Date: Dec. 31, 2020

(54) DISTANCE MEASURING METHOD AND DISTANCE MEASURING DEVICE

(71) Applicant: Panasonic Intellectual Property Management Co., Ltd., Osaka (JP)

(72) Inventors: Shinzo KOYAMA, Osaka (JP); Motonori ISHII, Osaka (JP); Yutaka HIROSE, Kyoto (JP); Akihiro ODAGAWA, Osaka (JP)

(21) Appl. No.: 16/644,473

(22) PCT Filed: Sep. 10, 2018
(86) PCT No.: PCT/JP2018/033363

§ 371 Date: Mar. 4, 2020

(30) Foreign Application Priority Data
Sep. 11, 2017 (JP) 2017-173859

(51) Int. Cl. G01S 17/14; G01S 7/4863; H01L 27/146; G01S 17/89

(52) U.S. Cl. CPC G01S 17/14; G01S 17/89; H01L 27/14614; G01S 7/4863

(57) ABSTRACT

A distance measuring method for use in a distance measuring device. The distance measuring device includes: a light source; a light-receiving element that receives light emitted from the light source, reflected by an object, and returned to the distance measuring device to generate an electric charge; a first capacitor and a second capacitor that store the electric charge; a transfer gate transistor that connects the light-receiving element and the first capacitor; and a reset transistor that connects the first capacitor and a voltage from an external source. The distance measuring method is a method of measuring a distance based on time taken by the light from the light source to return to the distance measuring device after being reflected by the object. The distance measuring method comprising: turning ON the transfer gate transistor; and turning OFF the reset transistor during a period in which the transfer gate transistor is ON.

### TECHNICAL FIELD

The present disclosure relates to a distance measuring method and a distance measuring device.

### BACKGROUND ART

While conventional solid-state imaging devices have focused on the capability of high-speed imaging of high-definition images, recent solid-state imaging devices have an additional capability of obtaining distance information from the devices. Images added with distance information enable the sensing of three-dimensional information on an imaging subject of a solid-state imaging device. A solid-state imaging device detects a gesture when shooting images of a person, for example, and thus finds its use as an input device of various types of devices. When installed on a vehicle, a solid-state imaging device recognizes the distance from an object or a person located around the own vehicle, and thus finds its application in, for example, collision avoidance, self-driving and so forth.

Time of flight (TOF) is amongst various methods used to measure the distance from a solid-state imaging device to an object. The TOF method measures the time taken by light to return to the solid-state imaging device after being radiated from around the solid-state imaging device toward an object and reflected by such object. While having a drawback in that it requires a light source in addition to the solid-state imaging device, when compared with other methods such as a compound eye method, TOF has the strength in that it is capable of high-resolution measurement of the distance to a far object by use of an enhanced light source. The technology described in patent literature (PTL) 1 is one example method of obtaining three-dimensional information by a solid-state imaging device with an application of the TOF method.

### CITATION LIST

### Patent Literature

PTL 1: Japanese Unexamined Patent Application Publication No. 2004-294420

### SUMMARY OF THE INVENTION

### Technical Problems

In PTL 1, received light (a light pulse reflected by an object) reaches the solid-state imaging device with time delay Td that corresponds to the distance to the object with respect to projected light (a light pulse emitted from the light source). An electric charge that is generated according to the received light incident to a light-receiving element, i.e., a photodiode (PD), is allocated to two nodes depending on the driving of two transfer gate transistors TX1 and TX2 to be generated as signals A and B. Subsequently, transfer gate transistors TX1 and TX2 are driven in a similar manner with the projected light OFF to obtain signals C and D. Signals A and B include background light components, but the subtractions of signals C and D to obtain signal (A-C) and signal (B-D) provides signals that include only received light components. Here, the ratio between signal (A-C) and signal (B-D) is determined by time delay Td, and thus distance information can be obtained.

The projected light is a pulse and the ratio between signal (A-C) and signal (B-D) represents a pulse phase, and thus such method will be referred to as a pulse phase method. The pulse phase method is effective when used for a relatively close distance (some meters distance) in an indoor environment with a relatively weak background light. The inventors have found, however, that the method has drawbacks as described below when used in an outdoor environment with intensive background light or used for a far distance.

A first drawback is a small dynamic range. Stated differently, the range of measurable distances is small. The intensity of received light is proportional to the square of the distance to an object. For example, the intensity ratio between the received light from an object at 1-meter distance and the received light from the same object at 100-meter distance is 10000:1. However, the number of saturated electrons in a single pixel of a solid-state imaging device is usually some 10000. When an optical condition capable of the detection of 100-meter distance is set to the method, the received light from the object at 1-meter distance is saturated, leading to the loss of pulse phase information. When the background light is intensive, saturation is further promoted.

A second drawback is poor resistance to intensive background light. More specifically, pulse width To of projected light is determined in accordance with the range of distance measurement. When the range of distance measurement is 100 meters, for example, To of 667 nanoseconds is required, which cannot be any shorter. Meanwhile, signals C and D obtained from the background light increase in proportion to To, and noise thereof, i.e., light shot noise, is proportional to the square root of signals C and D. When signals C and D are substantially equal to signals A and B, respectively, such light shot noise is extremely large, resulting in the failure of sufficiently accurate distance measurement.

In view of the above issues, the present disclosure aims to provide a solid-state imaging device, a distance measuring device, a distance measuring method, and a distance measuring device that cover a wider range of measurable distances.

The present disclosure also aims to provide a solid-state imaging device, a distance measuring device, a distance measuring method, and a distance measuring device capable of measuring a distance in an environment with intensive background light.

Other objects and novel features will be apparent from the explanation of the present description and the accompanying drawings.

### Solution to Problems

The following briefly explains the overview of a representative embodiment disclosed in the present application.

The distance measuring method according to one embodiment is a distance measuring method of measuring a distance based on time taken by a pulse light from a light source to return after reflected by an object, and outputting a distance image within one frame period. In this method, the one frame period includes a background light detection period, a distance measurement period, and a distance signal output period. A threshold is set in the background light detection period. The distance measurement period is divided into N periods, where N is an integer equal to or greater than 1. In the background light detection period, a transfer gate is turned ON, a reset signal is turned ON, and the reset signal is turned OFF during a period in which the transfer gate is turned ON. In the distance measurement period, the transfer gate is turned ON, the reset signal is turned ON, and the reset signal is turned OFF at a timing that is in a period in which the transfer gate is turned ON and that is delayed by a predetermined time from a time at which the light pulse has been emitted from the light source. In each of the N periods in the distance measurement period, the threshold and a count value are compared to store the time signal as a distance signal in a corresponding one of the periods in which the count value is greater than the threshold. In the distance signal output period, the distance signal is outputted as the distance image.

This configuration achieves distance measurement that covers a wide range of measurable distances.

### Advantageous Effect of Invention

An embodiment disclosed in the present disclosure provides a distance measuring method that covers a wide range of measurable distances.

### BRIEF DESCRIPTION OF DRAWINGS

FIG. 1 is a schematic diagram showing the configuration of a solid-state imaging device according to Embodiment 1.

FIG. 2 is a block diagram showing the structure of a pixel included in the solid-state imaging device according Embodiment 1.

FIG. 3 is a circuit diagram showing the structure of a pixel included in the solid-state imaging device according Embodiment 1.

FIG. 4 is a diagram showing operation periods included in one frame period of the solid-state imaging device according to Embodiment 1.

FIG. 5 is a diagram for explaining an operation sequence performed in a background light detection period by the solid-state imaging device according to Embodiment 1.

FIG. 6 is a diagram for explaining an operation sequence performed in a distance measurement period by the solid-state imaging device according to Embodiment 1.

### DESCRIPTION OF EXEMPLARY EMBODIMENT

The following describes an embodiment according to the present disclosure with reference to the drawings. Note that structural components that are substantially the same are assigned the same reference number, and repetitive description may be omitted. Also note that the following embodiment shows one specific illustration. The numerical values, shapes, materials, structural components, the arrangement and connection of the structural components, steps, the processing order of the steps, etc. shown in the following embodiments, etc. are mere examples, and thus are not intended to limit the present invention. Of the structural components described in the following embodiment, structural components not recited in any one of the independent claims that indicate the broadest concepts will be described as optional structural components.

### Embodiment 1

[1. Configuration of Solid-State Imaging Device]

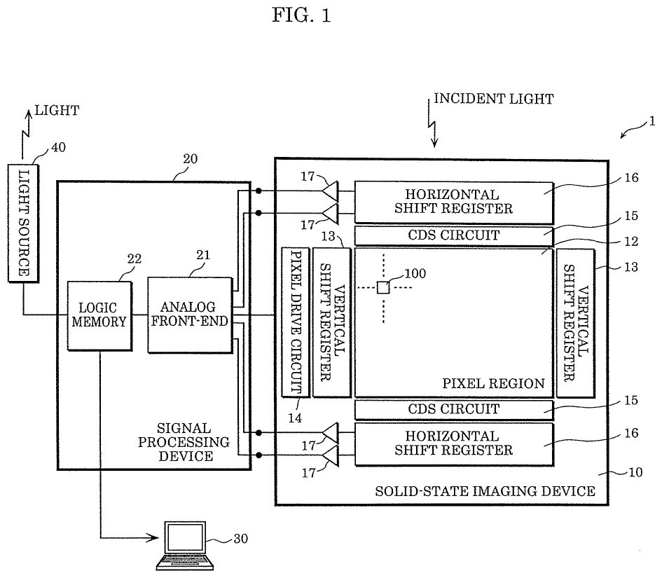

First, the configurations will be described of distance measuring device 1 and solid-state imaging device 10 according to the present embodiment. FIG. 1 is a schematic diagram showing the configuration of the distance measuring device that includes the solid-state imaging device according to the present embodiment.

As shown in FIG. 1, distance measuring device 1 includes solid-state imaging device 10, signal processing device 20, calculator 30, and light source 40.

Solid-state imaging device 10 has the configuration as described below, but the present disclosure is not limited to this.

As shown in FIG. 1, solid-state imaging device 10 includes pixel region 12, vertical shift registers 13, pixel drive circuit 14, correlated double sampling (CDS) circuits 15, horizontal shift registers 16, and output circuits 17.

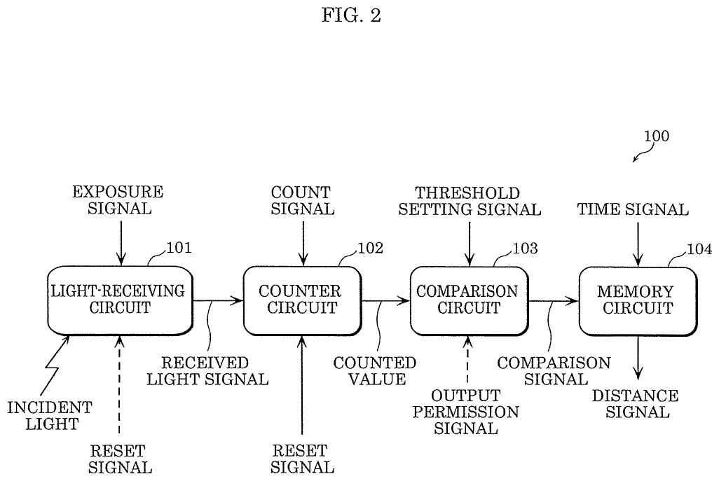

As shown in FIG. 2, pixel region 12 includes two-dimensionally arranged pixels 100.

Vertical shift registers 13 select pixels 100 in a specified row within pixel region 12. This function is mainly used to sequentially output distance signals from specified pixels 100.

Pixel drive circuit 14 is used to concurrently control all pixels 100 shown in FIG. 2.

CDS circuits 15 are circuits for removing offset components, included in the outputs from pixels 100 shown in FIG. 2, that are different from pixel 100 to pixel 100.

Horizontal shift registers 16 are circuits for sequentially selecting the outputs from the pixels in the column direction.

Each output circuit 17 outputs a distance signal from a pixel selected by vertical shift register 13 and horizontal shift register 16. In so doing, output circuit 17 amplifies the distance signal where necessary. The present solid-state imaging device 10 includes four output circuits 17, but a solid-state imaging device having the number of output circuits other than four is of course conceivable.

As shown in FIG. 1, signal processing device 20 includes analog front-end 21 and logic memory 22.

Analog front-end 21 converts analog output signals from solid-state imaging device 10 into digital output signals, and outputs the resulting signals to logic memory 22. In so doing, analog front-end 21 changes the order of output signals where necessary. The function of converting analog output signals into digital output signals is not necessary when output signals from solid-state imaging device 10 are digital output signals, but the function of changing the order of output signals is necessary. Output signals (distance signals) from signal processing device 20 are outputted to calculator 30.

Calculator 30, an example of which is a computer, constructs three-dimensional information on the surroundings of sold-state imaging device 10 on the basis of the output signals (distance signals) from signal processing device 20.

Light source 40 projects light at an area, the three-dimensional information on which is wished to be obtained. Light source 40 internally includes a mechanism of scattering light where necessary to radiate the light across the entirety of an area, the three-dimensional information on which is wished to be obtained. Light source 40 outputs pulsed light (pulse light) in the temporal direction. Signal processing device 20 controls the width and the time at which pulse light is outputted. Signal processing device 20 also controls solid-state imaging device 10 in synchronization with the control of light source 40. Solid-state imaging device 10 controls pixels 100 included therein via pixel drive circuit 14 and so forth, in accordance with signals from signal processing device 20.

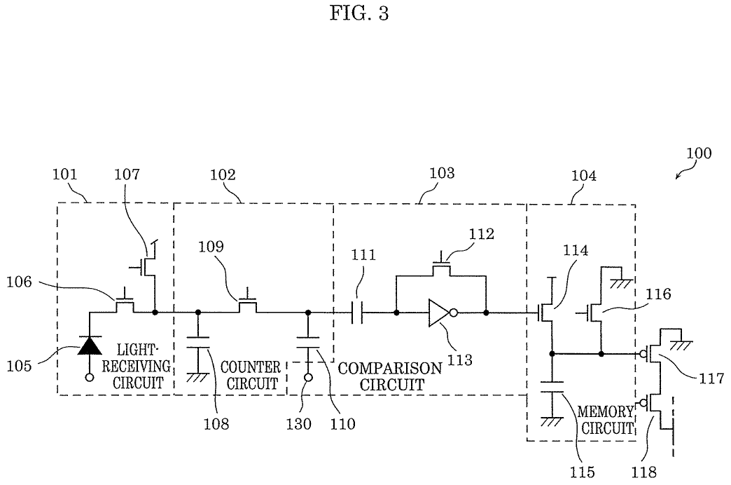

FIG. 2 is a block diagram showing the structure of pixel 100 included in solid-state imaging device 10 according the present embodiment. FIG. 3 is a circuit diagram showing the structure of pixel 100 included in solid-state imaging device 10 according the present embodiment. Note that in the following description of various signals, “ON” refers to a signal of a high-level voltage value and “OFF” refers to a signal of a low-level voltage value. Also, “turn ON” refers to applying a signal of a high-level voltage value and “turn OFF” refers to applying a signal of a low-level voltage value.

Pixel 100 shown in FIG. 2 internally includes four blocks: light-receiving circuit 101; counter circuit 102; comparison circuit 103; and memory circuit 104. The following describes the configuration and function of each of these blocks. Each of the blocks can allow for a certain extent of variation in the configuration required to have the function described below, but such variation is certainly equivalent to the present disclosure.

As shown in FIG. 3, light-receiving circuit 101 includes light-receiving element 105, transfer gate transistor 106, and reset transistor 107. Light-receiving element 105 and transfer gate transistor 106 are serially connected. Light-receiving element 105 and transfer gate transistor 106 make a pair. Transfer gate transistor 106 is connected in between light-receiving element 105 and counter circuit 102.

Light-receiving element 105 is, for example, a photodiode. Transfer gate transistor 106 transfers an electric charge generated in light-receiving element 105 through photoelectric conversion. This means that light-receiving circuit 101 internally includes the function of converting received incident light into a received light signal. A received light signal may vary depending on variations in the intensity of incident light, but it may take binary values depending on whether incident light has reached. The following description assumes that a received light signal is binary, but pixel 100 works when the received light signal is not binary. When the received light signal is not binary, binary values are used instead that are determined depending on whether a signal is greater or smaller than the threshold specified in the circuit. Also note that any timing can be set for photoelectric conversion in accordance with an exposure signal that is an input signal. Also, the function may be added of resetting a received light signal in response to a reset signal. The case where light has been received will be referred to as “a received light signal is present”, and the case where no light has been received will be referred to as “no received light signal is present”. When no reset function is added, the function is added instead of resetting an electric signal concurrently with the output of a received light signal, or within a sufficiently short period of time.

Pixel 100 shown in FIG. 2 further includes counter circuit 102 that is connected to the output of light-receiving circuit 101.

As shown in FIG. 3, counter circuit 102 includes electric charge storage capacitor 108, counter transistor 109, and counter capacitor 110. Output permission signal 130 is outputted via counter capacitor 110. Counter circuit 102 is added with the function of holding, incrementing, and resetting a count value. Counter circuit 102 resets the count value in response to a reset signal. Counter circuit 102 also detects a received light signal while a count signal, which is an input, is ON. When detecting a received light signal, counter circuit 102 increments the count value by one. Stated differently, counter circuit 102 counts the number of times a received light signal has reached received light circuit 101.

Pixel 100 shown in FIG. 2 further includes comparison circuit 103 that is connected to the output of counter circuit 102.

As shown in FIG. 3, comparison circuit 103 includes direct current cut capacitor 111, clamp transistor 112, and inverter 113. Comparison circuit 103 has the function of setting any threshold for the value of the number of times counted by counter circuit 102 and holding the set value. When a threshold setting signal, which is an input, is turned ON, a threshold is set in accordance with the count value, which is an input. The function is further added of turning a comparison signal ON when the count value is greater than the set threshold while the threshold setting signal is OFF. Alternatively, comparison circuit 103 may accept an input of an output permission signal. In this case, a comparison signal is turned ON only when the output permission signal is ON. The output permission signal will be described in Embodiment 2.

Pixel 100 shown in FIG. 2 further includes memory circuit 104.

As shown in FIG. 3, memory circuit 104 includes input transistor 114, memory capacitor 115, and memory node reset transistor 116. Memory circuit 104 has two inputs, one of which accepts an input of a comparison signal and the other of which accepts an input of a signal that varies in accordance with time, i.e., a time signal. Memory circuit 104 internally includes the function of storing the value of a time signal at the timing at which the comparison signal is turned ON. Certainly, memory circuit 104 is further added with the function of outputting the stored time signal (this signal is defined as a distance signal).

As shown in FIG. 3, memory circuit 104 is further connected to amplification transistor 117 and selection transistor 118.

Pixels 100 shown in FIG. 2 are two-dimensionally arranged inside solid-state imaging device 10. Distance measuring device 1 including solid-state imaging device 10 has the above configuration as shown in FIG. 1, but the present disclosure is not limited to this.

[2. Operation of Solid-State Imaging Device]

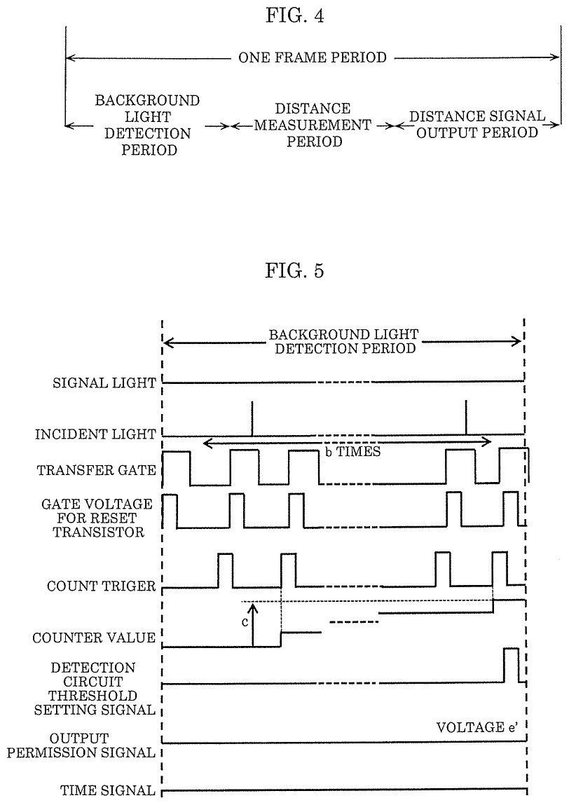

The following describes the operation performed by solid-state imaging device 10 according to the present embodiment. FIG. 4 is a diagram showing operation periods included in one frame period in solid-state imaging device 10.

As shown in FIG. 4, one frame period is divided into a background light detection period, a distance measurement period, and a distance signal output period. Solid-state imaging device 10 performs the operation of repeating the background light detection period, the distance measurement period, and the distance signal output period in stated order.

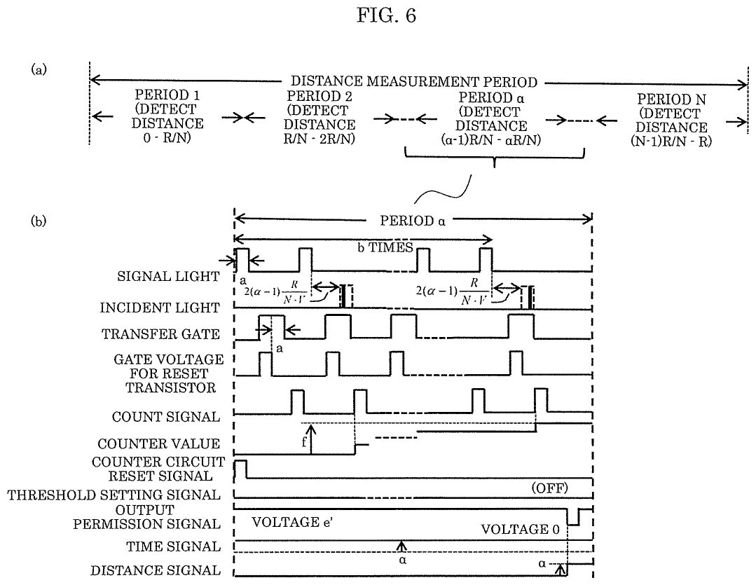

FIG. 5 is a diagram for explaining an operation sequence performed in the background light detection period by solid-state imaging device 10 according to the present embodiment. FIG. 6 is a diagram for explaining an operation sequence performed in the distance measurement period by solid-state imaging device 10 according to the present embodiment.

In the background light detection period, as shown in FIG. 5, signal light from light source 40 is turned OFF. In the background light detection period, incident light to solid-state imaging device 10 is only that of the background light. A transfer gate pulse is turned ON by the exposure signal, thereby turning ON transfer gate transistor 106. Note that reset transistor 107 is turned ON until the start of measurement while transfer gate transistor 106 is ON. The above settings enables light that reaches the light-receiving element before a predetermined signal detection period to be discharged via the reset transistor without being stored as an electric charge into electric charge storage capacitor 108.

Note that the timing at which transfer gate transistor 106 is turned ON and the timing at which reset transistor 107 is turned ON are not necessarily the same, and thus reset transistor 107 is simply required to be turned ON before a predetermined signal detection period.

Reset transistor 107 is turned OFF immediately before the start of measurement, with transfer gate transistor 106 remaining ON. When incident light is coming in after that, an electric charge corresponding to the incident light is stored into electric charge storage capacitor 108 via transfer gate transistor 106.

Transfer gate transistor 106 is then turned OFF. Subsequently, a counter trigger, which is a voltage to be applied to the gate of counter transistor 109, is turned ON, and its electric charge is transferred to counter capacitor 110.

After that, the counter trigger is turned OFF. Subsequently, transfer gate transistor 106 is turned ON again, and reset transistor 107 is turned ON at the same time, thereby resetting the electric charge in electric charge storage capacitor 108. These steps are repeated for b times.

Subsequently, the threshold setting signal is turned ON in comparison circuit 103 to be applied to clamp transistor 112, thereby storing the voltage in counter capacitor 110 corresponding to the background light as the voltage at both ends of direct current cut capacitor 111. While this is done, the voltage of the output permission signal is set at voltage E.

The distance measurement period is divided into a plurality of periods. FIG. 6 shows an operation sequence performed in the distance measurement period, where (a) represents the distance measurement period divided into a plurality of periods, and (b) represents an operation sequence performed in period α in (a).

First, in period a, a signal light pulse is emitted from the light source.

Transfer gate transistor 106 is turned ON at the same time at which the signal light pulse is emitted or at a timing that is delayed by a predetermined time from the time at which the signal light pulse is emitted. Reset transistor 107 is turned ON before the time represented by Expression 1 is elapsed after transfer gate transistor 106 is turned ON.

Subsequently, when the time represented by Expression 1 has elapsed, reset transistor 107 is turned OFF with transfer gate transistor 106 remaining ON.

Here, incident light received while reset transistor 107 is ON will be discharged via reset transistor 107 without being stored as an electric charge into electric charge storage capacitor 108. Stated differently, incident light received while reset transistor 107 is ON makes no contribution to measurement. This configuration accurately detects, as a signal, only light that reaches the device during a predetermined signal detection period (the period from when reset transistor 107 is turned OFF to when the transfer gate is turned OFF).

Furthermore, transfer gate transistor 106 remains ON for a predetermined period, after which transfer gate transistor 106 is turned OFF. Subsequently, the counter trigger is turned ON, and an electric charge generated in light-receiving element 105 is transferred to electric charge storage capacitor 108. In so doing, when the received light signal is present, the counter value is incremented by one. A series of these steps are repeated for b times.

Counter circuit 102 counts and stores the number of times light has reached out of the above b times of exposures. The description here assumes that light has reached for c times. Note, however, that the description here is based on the precondition that the above-described “a” is sufficiently small, or the incident light is regarded as being weak enough to split into some photons and continuously coming in. Usually, such precondition is well satisfied when “a” is equal to or less than some tens of nano.

Next, the threshold setting signal is turned ON for comparison circuit 103 to set the threshold that corresponds to c times, which is the output value from counter circuit 102. The threshold may be the value “c” per se, which is the output value from counter circuit 102, but the value that satisfies d=c+e (e is any positive value) is set here.

Next, an operation in the distance measurement period is performed. The description here assumes that an object is detected that is located within a distance measurement range from close range from solid-state imaging device 10 to R-meter distance. The description here also assumes that the resolution is R/N meters (N is an integer equal to or greater than 1). To achieve this, as shown in (a) and (b) of FIG. 6, the steps described below are performed in the distance measurement period.

First, as shown in (a) of FIG. 6, the distance measurement period is further divided into N periods. The divided sections are: period 1 for the detection of 0 to R/N meters; period 2 for the detection of R/N to 2R/N meters; . . . ; period α for the detection of (α−1)R/N to αR/N meters (a is an integer between 1 and N, inclusive), . . . ; and period N for the detection of (N−1)R/N to R meters. The division of the distance measurement period is not limited to this, and thus irregular pitch, for example, may be used. The description here assumes, however, that the distance measurement period is divided in the above manner.

Next, an operation performed in period a will be described. First, a counter circuit reset signal is turned ON to reset the counter value. Also, the time signal to input to memory circuit 104 is set to a. The time signal to input to memory circuit 104 may be any value so long as values are mutually different in period 1 through period N. Such value may also change continuously (in (b) of FIG. 6, the value is constant throughout period α).

Further, light source 40 is controlled to project a light pulse having the width of “a” seconds. When such light is incident to pixels within solid-state imaging device 10 after being reflected by an object located at a distance that corresponds to the distance to be measured in period α, i.e., located at (α−1)R/N to αR/N meter distance, a light pulse reflected by the object (to be referred to as received light) reaches solid-state imaging device 10 with a delay shown below with respect to the time at which the light pulse is emitted from the light source (to be referred to as projected light):

$$\begin{matrix}[ Math . 1 ] & \\ 2 ( α - 1 ) \frac{R}{N \cdot V} & ( Expression 1 )\end{matrix}$$

Here, V represents a light speed. Thus, after each of transfer gate transistor 106 and reset transistor 107 is turned ON, the reset transistor is turned OFF first at the time at which the light pulse reaches the solid-state imaging device, and then the transfer gate is turned OFF “a” seconds thereafter. This settings enables the detection of the received light from an object located within this distance range. Subsequently, counter circuit 102 counts the number of times the count signal has detected received light, i.e., the number of times light has reached.

The exposure is repeated for b times through the above-described procedure, and counter circuit 102 counts the number of times light has reached. When no object is present within the distance range corresponding to period α, the expected value of the count is c times, which is based on the background light components and smaller than threshold d. For this reason, no change will occur in the operation of comparison circuit 103 to be performed in the subsequent stage. When an object is present within the distance range corresponding to period α, the expected value of the count is f times, which is greater than c times. Stated differently, the following expression is satisfied when the intensity of the received light is sufficiently strong:

f>d (Expression 2)

Subsequently, the output permission signal is turned ON for comparison circuit 103. When Expression 2 is satisfied, the comparison signal is turned ON to store a time signal as a distance signal. When Expression 2 is unsatisfied, the distance signal stored (or, it can be the default value) will not change.

Period (α+1) lasts thereafter, and the distance measurement period ends with period N. At this time, memory circuit 104 in each pixel stores a signal that corresponds to the distance to an object, an image of which each pixel is to shoot, i.e., a distance signal.

In the end, the distance signal stored in each pixel is outputted in the distance signal output period. In the case of solid-state imaging device 10 in distance measuring device 1 shown in FIG. 1, vertical shift registers 13 and horizontal shift registers 16 sequentially select pixels, from which distance signals are outputted. Three-dimensional information (i.e., distance image) is obtained by processing these distance signals by signal processing device 20 and so forth. The following description can refer to a signal from solid-state imaging device 10 required to obtain a distance image simply as a distance image.

In the description so far, the exposure time in the background light detection period and the exposure time in the distance measurement period are the same, and the number of light pulses in the background light detection period and the number of light pulses in the distance measurement period are also the same, but the present disclosure is not limited to them. When different values are employed, however, a different prerequisite condition is employed to satisfy Expression 2 in accordance with such different values.

Also, the delay time of an exposure signal in each period with respect to the time at which a light pulse is emitted is not limited to this, and thus variations are easily conceivable.

The following describes the reason that distance measurement performed by solid-state imaging device 10 according to the present embodiment achieves a wider dynamic range of distance measurement than is achieved by the pulse phase method employed in the background art.

When simplified, the pulse phase method is a scheme that measures a distance on the basis of variations in the intensity of received light, and thus fails to measure a distance when the pixel saturation level is exceeded. The intensity of received light is indirectly proportional to the square of the distance to an object, and proportional to the reflectivity of an object. Assume, for example, that the maximum measurement distance is 100 meters and the reflectivity of a target object for measurement is 10% to 100%. In this case, the ratio between the intensity of received light from an object, located at 1-meter distance, having the reflectivity of 100%, and the intensity of received light from an object, located at 100-meter distance, having the reflectivity of 10% reaches 100000:1. Meanwhile, the number of saturated electrons of a single pixel in a typical solid-state imaging device is some 10000, suggesting that such typical device cannot simultaneously measure these two distances.

In the case of distance measurement by solid-state imaging device 10, on the other hand, the intensity of received light that is strong enough to satisfy Expression 2 is the only condition for carrying out measurement, and thus not affected by variations in the intensity of the received light attributable to the distance to an object and its reflectivity. It can be thus said that distance measurement by solid-state imaging device 10 achieves a distance dynamic range that is greater than that achieved by the pulse phase method.

The following describes the reason that distance measurement performed by solid-state imaging device 10 achieves better resistance to intensive background light than is achieved by the pulse phase method. A condition for measurement is that an object is detected that is located within a range from close range to R-meter distance as described above, and that a measurement accuracy of R/N meters is ensured.

In this case, the most affected by the background light is the measurement of an object at the furthest distance, i.e., at R-meter distance. This is because, while the reflected light intensity of the background light from an object is independent of the distance to the object, received light from the light source is indirectly proportional to the square of the distance. Stated differently, the SN ratio in received light is smaller as the distance is furtherer.

A condition for measurable received light is calculated below. The following assumes that energy unit is the number of photons. The following calculation assumes that the shot noise of the background light is a predominant in noise components, but the shot noise of the received light is small enough to be ignored.

Assume that the peak number of incident photons of received light into a single pixel per unit time is S (the value obtained by converting peak incident power into the number of photons). S is determined by the energy of the light source, the reflectivity of an object, and the distance thereto. Components attributable to the reflection of the background light at the object are superimposed simultaneously with the received light. Assume that the number of photons of the incident light components attributable to the background light per unit time is B. In the case of the pulse phase method, the pulse width must be:

$$\begin{matrix}[ Math . 2 ] & \\ \frac{2 R}{V} , & ( Expression 3 )\end{matrix}$$

and thus total energy T of the received light into a single pixel is:

$$\begin{matrix}[ Math . 3 ] & \\ T = S \cdot \frac{2 R}{V} \cdot M , & ( Expression 4 )\end{matrix}$$

where M is the number of pulses. Meanwhile, the total energy of the background light components is:

$$\begin{matrix}[ Math . 4 ] & \\ B \cdot \frac{2 R}{V} \cdot M , & ( Expression 5 )\end{matrix}$$

where the light shot noise below is superimposed:

$$\begin{matrix}[ Math . 5 ] & \\ \sqrt{B \cdot 2 \frac{R}{V} \cdot M} & ( Expression 6 )\end{matrix}$$

A necessary condition for calculating the accuracy R/N meters by use of the measured received light energy T is that T is measurable with the accuracy at or below T/N. Stated differently, the condition is as follows:

$$\begin{matrix}[ Math . 6 ] & \\ \frac{T}{N} > \sqrt{B \cdot 2 \frac{R}{V} \cdot M} \\ T > N \sqrt{B \cdot 2 \frac{R}{V} \cdot M} & ( Expression 7 )\end{matrix}$$

In contrast, expressions corresponding to Expression 7 for distance measurement performed by solid-state imaging device 10 are derived below. First, the width of a single light pulse and the exposure time for detecting the same are simply required to be equal to or less than the time taken to pass the double of the distance range corresponding to a single period at the light speed, i.e.:

$$\begin{matrix}[ Math . 7 ] & \\ 2 \frac{R}{VN} & ( Expression 8 )\end{matrix}$$

Here, the width of a single light pulse and the exposure time for detecting the same are assumed to be equal to Expression 8. The total energy of received light incident to a single pixel in a single period is as follows:

$$\begin{matrix}[ Math . 8 ] & \\ \frac{T}{N} & ( Expression 9 )\end{matrix}$$

Note, however, that the number of pulses and the peak energy in each period are assumed to be equal here. At the same time, the light energy of the incident background light is:

$$\begin{matrix}[ Math . 9 ] & \\ B \cdot 2 \frac{R}{VN} \cdot b , & ( Expression 10 )\end{matrix}$$

and the light shot noise of this light is:

$$\begin{matrix}[ Math . 10 ] & \\ \sqrt{B \cdot 2 \frac{R}{VN} \cdot b} & ( Expression 11 )\end{matrix}$$

Here, threshold d is required to be greater than the total of Expression 10 and Expression 11 at the minimum. Furthermore, threshold d is required to be still greater to avoid the misjudgment that received light has reached during a period in which no received light is supposed to reach. A statistical theory is that the probability of the light shot noise in Expression 11 becoming γ times greater than that in Expression 11 is: 16% when γ=1; 2.5% when γ=2; and 0.15% when γ=3. The probability smaller than 1/N does not result in the above misjudgment. When N=100, for example, γ=3 is simply required. Stated differently, threshold d is:

$$\begin{matrix}[ Math . 11 ] & \\ d = B \cdot 2 \frac{R}{VN} \cdot b + γ \cdot \sqrt{B \cdot 2 \frac{R}{VN} \cdot b} , & ( Expression 12 )\end{matrix}$$

and thus a necessary condition for measurement without any misjudgments is:

$$\begin{matrix}[ Math . 12 ] & \\ \frac{T}{N} > γ \cdot \sqrt{B \cdot 2 \frac{R}{VN} \cdot b} & ( Expression 13 )\end{matrix}$$

For simplification, the following considers the case where the same total number of pulses as that of the pulse phase method is used in distance measurement by solid-state imaging device 10. Stated differently, Expression 13 is as follows, when M=Nb is satisfied in distance measurement by solid-state imaging device 10, where M is the number of pulses in the pulse phase method,

N is the number of measurement periods, and b is the number of pulses in each measurement period:

$$\begin{matrix}[ Math . 13 ] & \\ T > \frac{γ}{N} \sqrt{B \cdot 2 \frac{R}{V} \cdot M} & ( Expression 14 )\end{matrix}$$

A comparison of Expression 14 and Expression 7 indicates that the distance measuring method performed by solid-state imaging device 10 is capable of performing measurement by use of smaller light source energy than is used by the pulse phase method, at least when N>γ is satisfied. More specifically, the distance measuring method performed by solid-state imaging device 10 has higher resistance to the background light. N>100 is at least required when distance measurement by solid-state imaging device 10 is used for gesture recognition, obstacle detection on a vehicle and so forth, and thus the distance measuring method performed by solid-state imaging device 10 requires substantially smaller light source energy than is required by the pulse phase method.

The following describes the reason that the accuracy of distance measurement is high when the background light components are weak. The description here assumes that the major noise component is the light shot noise of the received light components and the other nose is ignorable.

Considering that the light shot noise components of the received light components are equal to the light shot noise to received light energy T in the pulse phase method, the following expression is satisfied:

$$\begin{matrix}[ Math . 14 ] & \\ \sqrt{S \cdot 2 \frac{R}{V} \cdot M} & ( Expression 15 )\end{matrix}$$

A necessary condition for calculating the accuracy R/N meters is that T is measurable with the accuracy at or below T/N. Stated differently, the following expression is satisfied:

$$\begin{matrix}[ Math . 15 ] & \\ \frac{T}{N} > \sqrt{S \cdot 2 \frac{R}{V} \cdot M} \\ S > \frac{V}{2 RM} {N}^{2} & ( Expression 16 )\end{matrix}$$

For simplification, assuming that M=Nb is satisfied in distance measurement by solid-state imaging device 10, the number of received photons in a single measurement periods is:

$$\begin{matrix}[ Math . 16 ] & \\ S \cdot 2 \frac{R}{V} \frac{M}{N} & \end{matrix}$$

A necessary condition for obtaining the accuracy R/N meters is that the received light energy in a single measurement period is at least one photon. Stated differently, the following expression is satisfied:

$$\begin{matrix}[ Math . 17 ] & \\ S > \frac{V}{2 RM} N & ( Expression 17 )\end{matrix}$$

A comparison of Expression 16 and Expression 17 indicates that distance measurement performed by solid-state imaging device 10 is capable of performing measurement by use of smaller light energy than is used by the pulse phase method, when N>1. Conversely, when the same light energy is concerned, distance measurement by solid-state imaging device 10 achieves a higher accuracy of distance measurement.

As thus described, solid-state imaging device 10 according to the present embodiment is capable of performing distance measurement with a wider range of measurable distances.

### INDUSTRIAL APPLICABILITY

The solid-state imaging device according to the present invention is applicable for use as an automotive device for collision avoidance or self-driving, a distance measuring device and so forth.

### REFERENCE MARKS IN THE DRAWINGS

1 distance measuring device
10 solid-state imaging device
12 pixel region
13 vertical shift register
14 pixel drive circuit
15 CDS circuit
16 horizontal shift register
17 output circuit
20 signal processing device
21 analog front-end
22 logic memory
30 calculator
40 light source
100 pixel
101 light-receiving circuit
102 counter circuit
103 comparison circuit
104 memory circuit
105 light-receiving element
106 transfer gate transistor
107 reset transistor
108 electric charge storage capacitor
109 counter transistor
110 counter capacitor
111 direct current cut capacitor
112 clamp transistor
113 inverter
114 input transistor
115 memory capacitor
116 memory node reset transistor
117 amplification transistor
118 selection transistor
130 output permission signal

1. A distance measuring method for use in a distance measuring device that includes: a light source; a light-receiving element that receives light which has been emitted from the light source, reflected by an object, and returned to the distance measuring device to generate an electric charge; a first capacitor and a second capacitor that store the electric charge; a transfer gate transistor that connects the light-receiving element and the first capacitor; and a reset transistor that connects the first capacitor and a voltage from an external source, the distance measuring method being a method of measuring a distance based on time taken by the light from the light source to return to the distance measuring device after being reflected by the object, the distance measuring method comprising:
(1) turning ON the transfer gate transistor; and
(2) turning OFF the reset transistor during a period in which the transfer gate transistor is ON.

2. The distance measuring method according to claim 1, further comprising:
(3) turning ON the reset transistor at a timing that is before (2) is executed and that is included in the period.

3. The distance measuring method according to claim 2,
wherein the timing at which the reset transistor is turned ON in (3) coincides with a timing at which the transfer gate transistor is turned ON.

4. The distance measuring method according to claim 1,
wherein in (2), the reset transistor is turned OFF at a timing that is delayed by a predetermined time from a time at which the light is emitted.

5. The distance measuring method according to claim 1,
wherein the light is pulse light.

6. A distance measuring device comprising:
a light source;
a light-receiving element that receives light which has been emitted from the light source, reflected by an object, and returned to the distance measuring device to generate an electric charge;
a first capacitor and a second capacitor that store the electric charge;
a first transistor that connects the light-receiving element and the first capacitor;
a second transistor that connects the first capacitor and a voltage from an external source; and
a control circuit,
wherein the control circuit transmits to the first transistor a signal that turns ON the first transistor, and transmits to the second transistor a signal that turns OFF the second transistor in a period during which the first transistor is ON.

7. The distance measuring device according to claim 6,
wherein a signal that turns ON the second transistor is transmitted to the second transistor in the period.

8. The distance measuring device according to claim 7,
wherein the control circuit simultaneously transmits the signal that turns ON the first transistor and the signal that turns ON the second transistor.

9. The distance measuring device according to claim 6,
wherein the control circuit transmits to the second transistor the signal that turns OFF the second transistor at a timing that is delayed by a predetermined time from a time at which the light is emitted.

10. The distance measuring device according to claim 6,
wherein the light is pulse light.

11. The distance measuring device according to claim 6,
wherein the control circuit includes:
a counter circuit that counts a total number of times incident light has reached, based on the electric charge, and outputs the total number as a count value; and
a comparison circuit that outputs a comparison signal that enters an ON state when the count value is greater than a predetermined threshold.
